(19) United States
(12) Patent Application Publication
(10) Pub. No.: US 2020/0248316 A1
(43) Pub. Date: Aug. 6, 2020

(54) METHOD OF MANUFACTURING PLASMA-RESISTANT COATING FILM AND PLASMA-RESISTANT MEMBER FORMED THEREBY

(71) Applicant: KOMICO LTD., Anseong-si (KR)

(72) Inventors: Dae-Hoon JANG, Seoul (KR); Hyunchul KO, Anseong-si (KR); Dong-Joo KIM, Yongin-si (KR); Sang-Gyu PARK, Anseong-si (KR)

(21) Appl. No.: 16/652,063

(22) PCT Filed: Jul. 17, 2018
(86) PCT No.: PCT/KR2018/008075

§ 371 Date: Mar. 29, 2020

(30) Foreign Application Priority Data
Nov. 20, 2017 (KR) 10-2017-0155069

(51) Int. Cl. C23C 28/04; C23C 4/10; C23C 4/18; C23C 14/08; H01L 21/67; H01J 37/32

(52) U.S. Cl. CPC C23C 28/042; C23C 4/10; C23C 4/18; H01J 2237/334; H01L 21/67069; H01J 37/32495; C23C 14/083

(57) ABSTRACT

The present invention relates to a method of manufacturing a plasma-resistant coating film, including (1) forming a first rare-earth metal compound coating layer by subjecting a first rare-earth metal compound to thermal-spray coating on a coating object, (2) polishing the surface of the first rare-earth metal compound coating layer formed in step (1), and (3) forming a second rare-earth metal compound coating layer by subjecting a second rare-earth metal compound to aerosol deposition coating on the first rare-earth metal compound coating layer processed in step (2), the second rare-earth metal compound being the same component as the first rare-earth metal compound.

### BACKGROUND OF THE INVENTION

### 1. Technical Field

The present invention relates to a method of manufacturing a plasma-resistant coating film, and more particularly to a method of manufacturing a plasma-resistant coating film for use in a process of manufacturing a semiconductor including a semiconductor-etching device and a plasma-resistant member having the plasma-resistant coating film formed thereon.

### 2. Description of the Related Art

In general, the chamber of a device used in a process of manufacturing a semiconductor is made using a ceramic bulk such as an anodized aluminum alloy or alumina for insulation. Recently, as the need for corrosion resistance to highly corrosive gas or plasma used in the process of manufacturing a semiconductor using a deposition device for chemical vapor deposition (CVD), etc. or an etching device for plasma etching, etc., has further increased, in order to impart such high corrosion resistance, the chamber is manufactured through a process such as plasma spraying or thermal spraying of ceramics such as alumina and the like on the aluminum alloy.

Moreover, since the process of manufacturing a semiconductor performed in the chamber includes a large number of high-temperature processes such as heat treatment, chemical vapor deposition and the like, the chamber is also required to exhibit heat resistance. Specifically, the member of a device for manufacturing a semiconductor, such as the chamber, requires insulation properties, heat resistance, corrosion resistance and plasma resistance, and maintains strong bonding force between a coating layer and a substrate, so the coating layer is not peeled off, and thus it is necessary to minimize the generation of particles and the contamination of a wafer due thereto during the manufacturing process.

To this end, typically useful chemical vapor deposition, physical vapor deposition or sputtering may be applied. In this case, however, since the above process is used for a thin-film-manufacturing process, it is problematic because the processing time is too long to form a thick film that satisfies the requirements of corrosion resistance, etc., undesirably deteriorating economic efficiency, and also because it is difficult to obtain strong bonding force between the substrate and the coating layer.

Moreover, although a method of manufacturing a thick coating film through a plasma thermal-spray coating process in order to apply a thick film of 100 μm or more is disclosed in Korean Patent No. 10-0454987, there is a problem that it is difficult to manufacture a dense coating film when applying the thick film through the plasma thermal-spray coating process (Patent Document 0001).

Meanwhile, an aerosol deposition coating process may overcome the above problems and may produce a dense thick film, but a rare-earth metal compound makes it difficult to form a dense thick film of 100 μm or more. Therefore, the lifespan of the thick film, which is exposed to high voltage and plasma, may be shortened. Even in the case of aerosol deposition coating, which has been studied recently, it is technically possible to construct a film having a thickness of about 10 μm, but the film may peel off after use for a long time because of low adhesion due to simple mechanical engagement between the film and the surface. Furthermore, the film may be etched by CF₄ plasma ions and radicals used in a dry etching process, and thus particles may be generated, undesirably contaminating a wafer.

Next, the related art in the field to which the technology of the present invention belongs will be briefly described, and then distinguishing technical matters of the present invention will be described.

Specifically, Korean Patent No. 10-1108692 (Jan. 16, 2012) pertains to a dense rare-earth metal compound coating film for sealing a porous ceramic surface, and more particularly to a rare-earth metal compound coating film formed on a porous ceramic layer of a coating object including a porous ceramic layer having an average surface roughness of 0.4 to 2.3 μm, and the present invention discloses a manufacturing technique that has the effect of simultaneously ensuring voltage resistance by the porous ceramic coating layer having a sufficient thickness and ensuring plasma corrosion resistance by the dense rare-earth metal compound coating film, and which is applicable to various members for semiconductor devices including a semiconductor-etching device (Patent Document 0002).

In addition, Korean Patent Application Publication No. 10-2013-0123821 (Nov. 13, 2013) pertains to a plasma-resistant coating film including an amorphous first coating film formed by subjecting a thermal-spray coating powder composed of 30 to 50 wt % of aluminum oxide and 50 to 70 wt % of yttrium oxide to plasma thermal-spray coating on a coating object requiring plasma resistance and a second coating film formed on the first coating film through aerosol deposition coating and having a higher density and plasma resistance than the first coating film, and to a technique of manufacturing the plasma-resistant coating film imparted with plasma resistance, high voltage resistance and high electrical resistance (Patent Document 0003).

However, the plasma-resistant coating film manufactured in Patent Document 1 and Patent Document 2 includes the first coating film made of alumina and the second coating film made of a rare-earth metal compound, and there is a concern that the first coating film made of amorphous alumina may be etched when the second coating film is formed through aerosol deposition coating, undesirably causing a problem of decreased coating film uniformity. Furthermore, since the materials for the first coating film and the second coating film are different from each other and the bonding force between the coating layers varies, the possibility of peeling of the coating layer is high.

Also, Korean Patent Application Publication No. 10-2017-0080123 (Jul. 10, 2017) pertains to a plasma-resistant coating film, and particularly to a technique of manufacturing a plasma-resistant coating film, in which double sealing through aerosol deposition coating and hydration treatment, performed after thermal-spray coating of a first rare-earth metal compound, minimizes open channels and open pores in the coating layer to thus ensure both chemical resistance and plasma corrosion resistance by the dense rare-earth metal compound coating film (Patent Document 0004).

However, in the plasma-resistant coating film containing multiple coating layers, problems such as peeling and particle generation, which may be caused by deterioration of bonding force between the coating layers, still remain, and thus there is need for a technique of manufacturing a plasma-resistant coating film having durability and a long lifespan.

Hence, the present inventors have encountered limitations in the above methods of manufacturing the plasma-resistant coating film and have thoroughly studied methods of manufacturing a thin film having high plasma resistance while optimizing the bonding force between the coating layers, thus culminating in the present invention.

### SUMMARY OF THE INVENTION

Accordingly, an objective of the present invention is to provide a method of manufacturing a plasma-resistant coating film having high bonding force and improved plasma resistance.

Another objective of the present invention is to provide a plasma-resistant member including a plasma-resistant coating film formed using the method of manufacturing the plasma-resistant coating film.

In order to accomplish the above objectives, an embodiment of the present invention provides a method of manufacturing a plasma-resistant coating film, including (1) forming a first rare-earth metal compound coating layer by subjecting a first rare-earth metal compound to thermal-spray coating on a coating object, (2) polishing the surface of the first rare-earth metal compound coating layer formed in step (1), and (3) forming a second rare-earth metal compound coating layer by subjecting a second rare-earth metal compound to aerosol deposition coating on the first rare-earth metal compound coating layer processed in step (2), the second rare-earth metal compound being the same component as the first rare-earth metal compound.

In a preferred embodiment of the present invention, the first rare-earth metal compound coating layer has a thickness of 100 μm to 300 μm.

In a preferred embodiment of the present invention, the second rare-earth metal compound coating layer has a thickness of 1.0 μm to 30 μm.

In a preferred embodiment of the present invention, the first rare-earth metal compound is selected from the group consisting of yttria (Y₂O₃), yttrium fluoride (YF) and yttrium oxyfluoride (YOF).

In a preferred embodiment of the present invention, the average surface roughness of the first rare-earth metal compound coating layer through the polishing in step (2) is 0.1 μm to 3.0 μm.

In a preferred embodiment of the present invention, the second rare-earth metal compound coating layer has a porosity of 1 vol % or less.

Another embodiment of the present invention provides a plasma-resistant member including a coating object requiring plasma resistance and a composite plasma-resistant coating film formed on the surface of the coating object, in which the plasma-resistant coating film includes a first rare-earth metal compound coating layer and a second rare-earth metal compound coating layer, the first rare-earth metal compound coating layer is formed by subjecting a first rare-earth metal compound to thermal-spray coating and the surface of the first rare-earth metal compound coating layer is processed so as to have an average surface roughness of 0.1 μm to 3.0 μm, the second rare-earth metal compound coating layer is formed by subjecting a second rare-earth metal compound to aerosol deposition coating on the first rare-earth metal compound coating layer, and the second rare-earth metal compound is the same component as the first rare-earth metal compound.

In a preferred embodiment of the present invention, the first rare-earth metal compound coating layer has a thickness of 100 μm to 300 μm.

In a preferred embodiment of the present invention, the second rare-earth metal compound coating layer has a thickness of 1.0 μm to 30 μm.

In a preferred embodiment of the present invention, the first rare-earth metal compound is selected from the group consisting of yttria (Y₂O₃), yttrium fluoride (YF) and yttrium oxyfluoride (YOF).

In a preferred embodiment of the present invention, the second rare-earth metal compound coating layer has a porosity of 1 vol % or less.

According to the present invention, a plasma-resistant coating film including a first rare-earth metal compound coating layer and a second rare-earth metal compound coating layer can exhibit high bonding force between a substrate and the first rare-earth metal compound coating layer and improved plasma resistance by virtue of the dense second rare-earth metal compound coating layer.

Moreover, a method of manufacturing the plasma-resistant coating film according to the present invention enables the formation of a uniform plasma-resistant coating film on various types of semiconductor device members, and a plasma-resistant member according to the present invention can exhibit improved plasma resistance and thus high resistance to contaminants during the manufacture of a semiconductor.

### BRIEF DESCRIPTION OF DRAWINGS

FIG. 1 schematically shows the structure of a plasma-resistant coating film including a first rare-earth metal compound coating layer and a second rare-earth metal compound coating layer according to the present invention and a process of manufacturing the same;

FIG. 2 is a scanning electron microscope (SEM) image of a plasma-resistant coating film including a first yttria coating layer and a second yttria coating layer manufactured in Example 1; and

FIG. 3 shows images after etching testing of (a) alumina (Al₂O₃), (b) quartz, (c) yttria (Y₂O₃, bulk), (d) yttria (Y₂O₃, AD coating), and (e) yttria (Y₂O₃, APS).

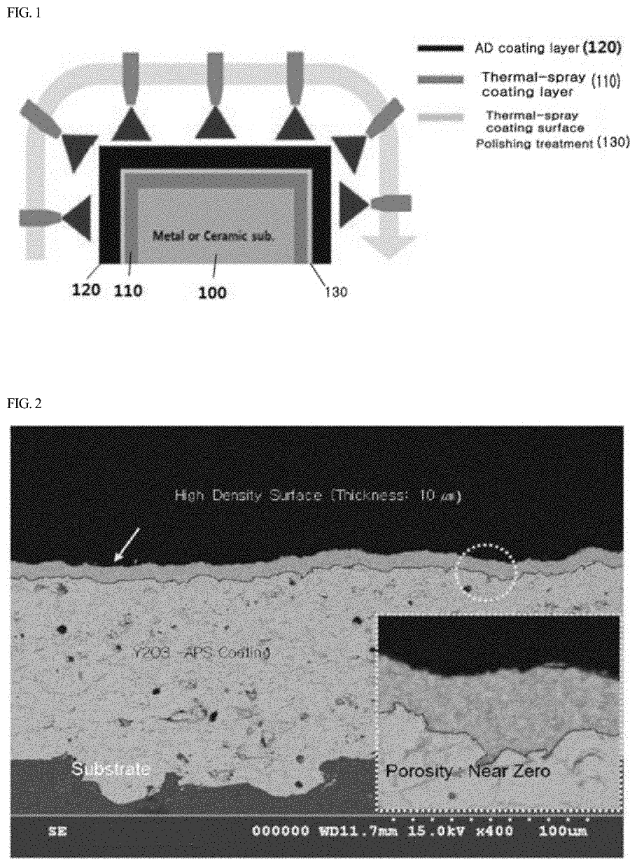

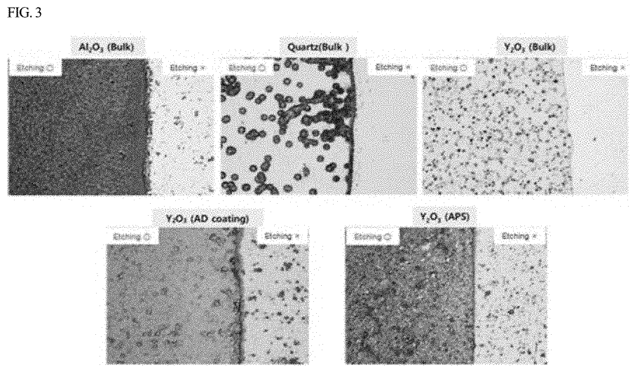

### DESCRIPTION OF SPECIFIC EMBODIMENTS

Unless otherwise defined, all technical and scientific terms used herein have the same meanings as those typically understood by those skilled in the art to which the present invention belongs. Generally, the nomenclature used herein is well known in the art and is typical.

As used herein, when any part is said to “include” any element, this does not mean that other elements are excluded, and such other elements may be further included unless otherwise specifically mentioned.

An aspect of the present invention pertains to a method of manufacturing a plasma-resistant coating film, including (1) forming a first rare-earth metal compound coating layer by subjecting a first rare-earth metal compound to thermal-spray coating on a coating object, (2) polishing the surface of the first rare-earth metal compound coating layer formed in step (1), and (3) forming a second rare-earth metal compound coating layer by subjecting a second rare-earth metal compound to aerosol deposition coating on the first rare-earth metal compound coating layer processed in step (2), the first rare-earth metal compound in step (1) and the second rare-earth metal compound in step (2) being the same component.

More specifically, the method of manufacturing the plasma-resistant coating film according to the present invention includes, as shown in FIG. 1, forming a first rare-earth metal compound coating layer 110 through thermal-spray coating on a coating object 100, subjecting the first rare-earth metal compound coating layer 110 to surface processing so that the average surface roughness thereof is 0.1 μm to 3.0 μm, and forming a second rare-earth metal compound coating layer 120 on the surface-processed first rare-earth metal compound coating layer 110 through aerosol deposition coating (AD coating) having high coating density, thereby obtaining a plasma-resistant coating film having high bonding force between coating layers and high plasma resistance.

In the method of manufacturing the plasma-resistant coating film according to the present invention, the first rare-earth metal compound coating layer 110 is formed by subjecting the first rare-earth metal compound to thermal-spray coating on the coating object 100 [step (1)].

The coating object 100 on which the first rare-earth metal compound coating layer is formed may be a plasma device part that is applied to the inside of a plasma device, such as an electrostatic chuck, a heater, a chamber liner, a shower head, a boat for CVD, a focus ring, a wall liner, etc., and the material for the coating object may include, but is not limited to, metal such as iron, magnesium, aluminum, alloys thereof, etc., ceramic, such as SiO₂, MgO, CaCO₃, alumina, etc., a polymer, such as polyethylene terephthalate, polyethylene naphthalate, polypropylene adipate, polyisocyanate, etc., and the like.

Moreover, the coating object 100 is subjected to surface sanding treatment and is thus imparted with surface roughness of a certain level, and also, adhesion between the coating object and the first rare-earth metal compound coating layer that is subsequently formed may be enhanced.

For example, if the surface roughness of the coating object 100 through sanding treatment is less than 1 μm, adhesion between the coating object and the first rare-earth metal compound coating layer that is subsequently formed may decrease, undesirably facilitating peeling of the first rare-earth metal compound coating layer from the coating object due to external impact. On the other hand, if the surface roughness of the coating object through sanding treatment exceeds 8 μm, it may affect the surface roughness of the first rare-earth metal compound coating layer that is subsequently formed, and thus the second rare-earth metal compound coating layer may not be formed at a uniform thickness on the first rare-earth metal compound coating layer, which is undesirable. In the present embodiment, the coating object may be subjected to sanding treatment so as to have a surface roughness corresponding to an average center roughness of about 1 μm to 8 μm.

In order to form the first rare-earth metal compound coating layer 110 on the coating object, any process may be applied without limitation, so long as it is thermal-spray coating for forming a coating layer that satisfies requirements such as high bonding force between the coating object and the coating layer and high corrosion resistance. Preferably, a plasma thermal-spray coating process is performed in order to attain high hardness of the coating layer and high electrical resistance.

In step (1), the first rare-earth metal compound coating layer 110 is a layer that is formed by subjecting the first rare-earth metal compound to thermal-spray coating on the coating object 100, and preferably has a thickness of 100 μm to 300 μm. If the thickness of the first rare-earth metal compound coating layer is less than 100 μm, voltage resistance may decrease, which is undesirable. On the other hand, if the thickness thereof exceeds 300 μm, the processing time may increase, undesirably lowering productivity.

The first rare-earth metal compound may be selected from the group consisting of yttria (Y₂O₃), yttrium fluoride (YF) and yttrium oxyfluoride (YOF), and is preferably yttria (Y₂O₃).

The first rare-earth metal compound, which constitutes the first rare-earth metal compound coating layer, has high resistance to the plasma when exposed thereto during semiconductor processing, thereby ensuring voltage resistance and plasma corrosion resistance during semiconductor processing when applied to a semiconductor device part requiring corrosion resistance, such as a semiconductor-etching device.

The first rare-earth metal compound coating layer 110 is subjected to surface processing so that the average surface roughness thereof is 0.1 μm to 3.0 μm [step (2)].

In the method of manufacturing the plasma-resistant coating film according to the present invention, step (2) is processing the surface of the first rare-earth metal compound coating layer formed in step (1) so as to have an average surface roughness of 0.1 μm to 3.0 μm. Specifically, the first rare-earth metal compound coating layer formed in step (1) is subjected to grinding so as to have a uniform thickness and then to surface roughening so that the surface of the first rare-earth metal compound coating layer has an average surface roughness of 0.1 μm to 3.0 μm. Here, the above processing may be performed through polishing using a diamond pad, but is not limited thereto. In addition to polishing using the diamond pad, polishing may be performed through chemical mechanical polishing (CMP) or other polishing procedures.

The surface of the first rare-earth metal compound coating layer formed in step (1) may be roughened through the above processing so as to have an average surface roughness of 0.1 μm to 3.0 μm, thereby enhancing adhesion between the first rare-earth metal compound coating layer and the second rare-earth metal compound coating layer. If the average surface roughness of the metal compound coating layer exceeds 3.0 μm, the surface roughness may be excessively increased, making it difficult to form a desired coating layer on the first rare-earth metal compound coating layer, which causes layer peeling.

In order to form a denser coating layer on the first rare-earth metal compound coating layer 110, the second rare-earth metal compound coating layer 120 is formed by depositing the second rare-earth metal compound using aerosol deposition coating (AD coating) [step (3)].

The second rare-earth metal compound coating layer 120 is a high-density rare-earth metal compound layer having a porosity of 1 vol % or less formed on the first rare-earth metal compound coating layer through aerosol deposition coating, and preferably has a thickness of 1 μm to 30 μm and a surface roughness corresponding to an average center roughness of 0.1 μm to 3.0 μm. The surface roughness of the second rare-earth metal compound coating layer is determined by the initial surface roughness of the substrate and the increased thickness of the coating layer.

As the porosity of the second rare-earth metal compound coating layer increases, the mechanical strength of the plasma-resistant coating film that is ultimately formed may deteriorate, which is undesirable. Thus, it is preferred that the second rare-earth metal compound coating layer have low porosity and be dense in order to ensure the mechanical strength of the plasma-resistant coating film and the electrical properties thereof.

If the thickness of the second rare-earth metal compound coating layer is less than 1 μm, the thickness thereof is excessively low, making it difficult to ensure plasma resistance in a plasma environment. On the other hand, if the thickness of the second rare-earth metal compound coating layer exceeds 30 μm, peeling may occur due to residual stress of the coating layer, and may also take place even during processing. Furthermore, overuse of the rare-earth metal compound is uneconomical.

Moreover, as the surface roughness of the second rare-earth metal compound coating layer, which is the surface layer of the plasma-resistant coating film according to the present invention, is lower, the generation of particles may be reduced.

In order to form the second rare-earth metal compound coating layer, aerosol deposition coating may be conducted in a manner in which a second rare-earth metal compound powder having a particle size of 0.1 μm to 20 μm is placed in an aerosol chamber and the coating object is seated in a deposition chamber. Here, the second rare-earth metal compound powder is applied in the aerosol chamber, and is incident into the aerosol chamber through argon gas and is thus aerosolized. The carrier gas may include, in addition to argon gas, compressed air, inert gas such as hydrogen (H₂), helium (He) or nitrogen (N₂), and the like. The second rare-earth metal compound powder is sucked together with the carrier gas into the deposition chamber due to the difference in pressure between the aerosol chamber and the deposition chamber, and is sprayed at a high speed onto the coating object via a nozzle. Thereby, the second rare-earth metal compound is deposited through the above spraying, thus forming a high-density second rare-earth metal compound coating layer. The area of the second rare-earth metal compound coating layer that is deposited is controllable to a desired size by moving the nozzle from side to side, and the thickness thereof is also determined in proportion to the deposition time, that is, the spraying time.

The second rare-earth metal compound coating layer 120 may be formed by stacking the second rare-earth metal compound through two or more aerosol deposition coating processes.

In the present invention, the second rare-earth metal compound is the same as the first rare-earth metal compound, thereby increasing the bonding force between the first rare-earth metal compound coating layer and the second rare-earth metal compound coating layer to thus minimize the peeling of the coating layer and the generation of particles during the manufacturing process and the contamination of a wafer due thereto.

The aerosol deposition coating is preferably conducted using medical-grade compressed air. The use of medical-grade compressed air is effective at preventing a problem in which aerosolization does not occur due to moisture typically contained in air and also preventing impurities such as oil in air from being incorporated in the film during aerosol deposition coating.

The method of manufacturing the plasma-resistant coating film according to the present invention enables the formation of a uniform thin film on the 3D surface of the plasma-resistant member through one-stop coating. Conventionally, section coating is performed depending on the shape of the product, and thus the coating layer at the boundary of the sections is non-uniform, but when the one-stop coating process proceeds, the boundary coating layer may be manufactured in the form of a uniform thin film. Accordingly, it is possible to form a uniform coating film on various types of substrates when manufacturing a coating film using a one-stop coating process.

Another aspect of the present invention pertains to a plasma-resistant member including a coating object requiring plasma resistance and a composite plasma-resistant coating film formed on the surface of the coating object, in which the plasma-resistant coating film includes a first rare-earth metal compound coating layer and a second rare-earth metal compound coating layer, the first rare-earth metal compound coating layer is formed by subjecting a first rare-earth metal compound to thermal-spray coating, the surface of the first rare-earth metal compound coating layer is processed so as to have an average surface roughness of 0.1 μm to 3.0 μm, the second rare-earth metal compound coating layer is formed by subjecting a second rare-earth metal compound to aerosol deposition coating on the first rare-earth metal compound coating layer, and the first rare-earth metal compound and the second rare-earth metal compound are the same component.

A better understanding of the present invention will be given through the following examples. However, the following examples are merely set forth to illustrate the present invention, and are not to be construed as limiting the present invention.

### COMPARATIVE EXAMPLES 1 to 3

Alumina (Al₂O₃), quartz, and yttria (Y₂O₃), which were in a solid phase, were used without processing in Comparative Example 1, Comparative Example 2 and Comparative Example 3, respectively.

### COMPARATIVE EXAMPLE 4

A yttria coating layer having a thickness of 10 (±5) μm was formed by aerosolizing a yttria (Y₂O₃) powder in an aerosol chamber in a vacuum at room temperature and then subjecting the aerosolized yttria (Y₂O₃) powder to physical collision with argon gas on a substrate using a difference in pressure between the aerosol chamber and the deposition chamber.

### COMPARATIVE EXAMPLE5

A yttria coating layer having a thickness of 100 μm was formed by subjecting a yttria (Y₂O₃) thermal-spray coating powder having an average particle size of 30 μm to plasma thermal-spray coating (helium and argon processing gases, 3000 K heat source) on a substrate.

### COMPARATIVE EXAMPLE6

6-1: Formation of Alumina Coating Layer An alumina coating layer having a thickness of 100 μm was formed by subjecting an alumina (Al₂O₃) thermal-spray coating powder having an average particle size of 30 μm to plasma thermal-spray coating (helium and argon processing gases, 3000 K heat source) on a substrate.

6-2: Surface Processing of Alumina Coating Layer

The alumina coating layer was subjected to surface processing through polishing using a diamond pad so that the surface roughness thereof was 3 μm or less.

6-3: Formation of Yttria Coating Layer

A yttria coating layer having a thickness of 10 (±5) μm was formed by aerosolizing a yttria (Y₂O₃) powder in an aerosol chamber in a vacuum at room temperature and then subjecting the aerosolized yttria (Y₂O₃) powder to physical collision with argon gas on the surface-processed alumina coating layer using a difference in pressure between the aerosol chamber and the deposition chamber.

### EXAMPLE 1

1-1: Formation of First Yttria Coating Layer

A first yttria coating layer having a thickness of 100 μm was formed by subjecting a yttria (Y₂O₃) thermal-spray coating powder having an average particle size of 30 μm to plasma thermal-spray coating (helium and argon processing gases, 3000 K heat source) on a substrate.

1-2: Surface Processing of First Yttria Coating Layer

The first yttria coating layer was subjected to surface processing through polishing using a diamond pad so that the surface roughness thereof was 3 μm or less.

1-3: Formation of Second Yttria Coating Layer

A second yttria coating layer having a thickness of 10 μm was formed by aerosolizing a yttria (Y₂O₃) powder in an aerosol chamber in a vacuum at room temperature and then subjecting the aerosolized yttria (Y₂O₃) powder to physical collision with argon gas on the surface-processed first yttria coating layer using a difference in pressure between the aerosol chamber and the deposition chamber.

### TEST EXAMPLE 1

The plasma-etching rates of the coating films manufactured in Comparative Examples and Example of the present invention were measured using Unaxis, VLICP (etching: CF₆/C₄F₈/CH₂F₂/CF₄/O₂/Ar, flow rate: 30/5/10 sccm, chamber pressure: 0.1 torr, power: 5000 W). The results thereof are shown in Tables 1 and 2 below.

TABLE 1

| | | Coating | Etching rate |
|---|---|---|---|
| No. | Type | Material | (μm/hr) |
| Comparative | Bulk | Al₂O₃ | 9.01 |
| Example 1 | | | |
| Comparative | Bulk | Quartz | 41.06 |
| Example 2 | | | |
| Comparative | Bulk | Y₂O₃ | 0.41 |
| Example 3 | | | |
| Comparative | AD coating | Y₂O₃ | 2.28 |
| Example 4 | | | |
| Comparative | Thermal-spray | Y₂O₃ | 3.00 |
| Example 5 | coating | | |

As is apparent from Table 1, Comparative Example 4 exhibited a low plasma-etching rate compared to Comparative Example 5, indicating that the plasma resistance of the coating film formed through aerosol deposition coating for forming a dense thin film was higher than that of the coating film formed through thermal-spray coating. On the other hand, Comparative Example 3 exhibited a low etching rate compared to Comparative Examples 1 and 2, which shows the difference in plasma resistance depending on the kind of material, indicating that yttria has higher plasma resistance than alumina or quartz.

TABLE 2

| | First coating | | |
|---|---|---|---|
| | layer | Second | |
| | Thermal- | coating | |
| | spray | layer | Comparison of total etching |
| | coating | AD coating | time to completely remove |
| No. | (100 μm) | (10 μm) | A and B coating layers |
| Example 1 | Y₂O₃ | Y₂O₃ | A + B ≈ 37 min |
| Comparative | Al₂O₃ | Y₂O₃ | A + B ≈ 6 min |
| Example 6 | | | |

As is apparent from Table 2, Example 1 exhibited a low plasma-etching rate compared to Comparative Example 6. This is deemed to be because the high etching rate of the coating film manufactured in Comparative Example 6 is due to the first coating layer made of amorphous alumina. The time taken to completely remove the coating film including the first coating layer made of yttria having higher plasma resistance, which was manufactured in Example 1, was over 6 times as long as that of the coating film manufactured in Comparative Example 6.

Although specific embodiments of the present invention have been disclosed in detail as described above, it will be obvious to those skilled in the art that the description is merely of preferable exemplary embodiments and is not to be construed to limit the scope of the present invention. Therefore, the substantial scope of the present invention will be defined by the appended claims and equivalents thereof.

What is claimed is:

1. A method of manufacturing a plasma-resistant coating film, comprising:
(1) forming a first rare-earth metal compound coating layer by subjecting a first rare-earth metal compound to thermal-spray coating on a coating object;
(2) polishing a surface of the first rare-earth metal compound coating layer formed in step (1); and
(3) forming a second rare-earth metal compound coating layer by subjecting a second rare-earth metal compound to aerosol deposition coating on the first rare-earth metal compound coating layer processed in step (2),
wherein the second rare-earth metal compound is a same component as the first rare-earth metal compound.

2. The method of claim 1, wherein the first rare-earth metal compound coating layer has a thickness of 100 μm to 300 μm.

3. The method of claim 1, wherein the second rare-earth metal compound coating layer has a thickness of 1.0 μm to 30 μm.

4. The method of claim 1, wherein the first rare-earth metal compound is selected from the group consisting of yttria (Y₂O₃), yttrium fluoride (YF) and yttrium oxyfluoride (YOF).

5. The method of claim 1, wherein an average surface roughness of the first rare-earth metal compound coating layer through the polishing in step (2) is 0.1 μm to 3.0 μm.

6. The method of claim 1, wherein the second rare-earth metal compound coating layer has a porosity of 1 vol % or less.

7. A plasma-resistant member, comprising:
a coating object requiring plasma resistance; and
a composite plasma-resistant coating film formed on a surface of the coating object,
wherein the plasma-resistant coating film comprises a first rare-earth metal compound coating layer and a second rare-earth metal compound coating layer,
the first rare-earth metal compound coating layer is formed by subjecting a first rare-earth metal compound to thermal-spray coating and a surface of the first rare-earth metal compound coating layer is processed so as to have an average surface roughness of 0.1 μm to 3.0 μm,
the second rare-earth metal compound coating layer is formed by subjecting a second rare-earth metal compound to aerosol deposition coating on the first rare-earth metal compound coating layer, and
the second rare-earth metal compound is a same component as the first rare-earth metal compound.

8. The plasma-resistant member of claim 7, wherein the first rare-earth metal compound coating layer has a thickness of 100 μm to 300 μm.

9. The plasma-resistant member of claim 7, wherein the second rare-earth metal compound coating layer has a thickness of 1.0 μm to 30 μm.

10. The plasma-resistant member of claim 7, wherein the first rare-earth metal compound is selected from the group consisting of yttria (Y₂O₃), yttrium fluoride (YF) and yttrium oxyfluoride (YOF).

11. The plasma-resistant member of claim 7, wherein the second rare-earth metal compound coating layer has a porosity of 1 vol % or less.
